(19) United States
(12) Patent Application Publication
(10) Pub. No.: US 2026/0165161 A1
(43) Pub. Date: Jun. 11, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Tsung-Yu Yang, Chiayi County (TW); Cheng-Tzung Tsai, Taipei City (TW); Yuan-Chih Liu, Tainan City (TW); Chang-Ta Chiang, Hsinchu City (TW)

(73) Assignee: UNITED MICROELECTRONICS CORP., Hsin-Chu City (TW)

(21) Appl. No.: 19/012,795

(22) Filed: Jan. 7, 2025

(30) Foreign Application Priority Data
Dec. 10, 2024 (TW) 113147761

(51) Int. Cl. H01L 23/00; H01L 23/498

(52) U.S. Cl. CPC H10W 70/65; H10W 72/01951; H10W 72/01953; H10W 72/923; H10W 72/934; H10W 72/952; H10W 72/953

(57) ABSTRACT

A method for fabricating a semiconductor device includes the steps of first forming an inter-metal dielectric ((IMD) layer on a substrate and a metal interconnection in the IMD layer, forming a dielectric layer on the IMD layer, patterning the dielectric layer to form an opening, forming a bonding pad in the opening, and then forming a passivation layer on the bonding pad. Preferably, a top surface of the bonding pad includes a first curve and a sidewall of the bonding pad includes a second curve.

### BACKGROUND OF THE INVENTION

### 1. Field of the Invention

The invention relates to a method for fabricating semiconductor device, and more particularly to a method of forming curved surface on top surface of bonding pad.

### 2. Description of the Prior Art

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (PoP) devices and so on.

3DICs provide improved integration density and other advantages, such as faster speeds and higher bandwidth, because of the decreased length of interconnects between the stacked chips. However, there are quite a few challenges to be handled for the technology of 3DICs.

### SUMMARY OF THE INVENTION

According to an embodiment of the present invention, a method for fabricating a semiconductor device includes the steps of first forming an inter-metal dielectric ((IMD) layer on a substrate and a metal interconnection in the IMD layer, forming a dielectric layer on the IMD layer, patterning the dielectric layer to form an opening, forming a bonding pad in the opening, and then forming a passivation layer on the bonding pad. Preferably, a top surface of the bonding pad includes a first curve and a sidewall of the bonding pad includes a second curve.

According to another aspect of the present invention, a semiconductor device includes an inter-metal dielectric ((IMD) layer on a substrate and a metal interconnection in the IMD layer, a dielectric layer on the IMD layer, and a bonding pad on the dielectric layer. Preferably, a top surface of the bonding pad includes a first curve.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,”“an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,”“upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

Referring to FIGS. 1-5, FIGS. 1-5 illustrate a method for fabricating a semiconductor device according to an embodiment of the present invention. As shown in FIG. 1, a substrate 12 made of semiconductor material is provided. Preferably, the substrate 12 could be made of semiconductor substrate material including but not limited to for example silicon wafer, silicon substrate, epitaxial silicon substrate, silicon carbide substrate or even a silicon-on-insulator (SOI) substrate, which are all within the scope of the present invention. In this embodiment, the substrate 12 could be used for fabricating elements including MV devices, HV devices, pixel circuits, LV devices for LV driving circuits, and/or graphics process unit (GPU).

Next, a front end of line (FEOL) and a back end of line (BEOL) fabrication processes could be conducted on the substrate 12. In this embodiment, the FEOL process could include the process of forming metal-oxide semiconductor (MOS) transistors, oxide semiconductor field effect transistors (OS FETs), fin field effect transistor (FinFETs), or other active devices and/or passive devices. BEOL process on the other hand could include forming metal interconnect structures such as metal inter-metal dielectric (IMD) layers and metal interconnections on the aforementioned active devices and/or passive devices.

If a MOS transistor were to be fabricated, the FEOL process could include the steps of forming a gate structure on the substrate, forming a spacer (not shown) adjacent to sidewalls of the gate structure and a source/drain region in the substrate adjacent to two sides of the spacer, in which the gate structure could include polysilicon or metal, the spacer could include dielectric material such as silicon oxide or silicon nitride, and the source/drain region could include p-type dopants or n-type dopants depending on the conductive type of the transistor being fabricated.

Next, an interlayer dielectric (ILD) layer could be formed on the substrate 12 to cover the MOS transistor or other active devices, and then a contact plug formation and metal interconnect process from BEOL process could be conducted to form a plurality of contact plugs in the ILD layer for connecting the source/drain region and the gate structure, an inter-metal dielectric (IMD) layer 14 disposed on the ILD layer, and metal interconnections 16 in the IMD layer 14 for connecting the contact plugs, in which the topmost metal interconnection 16 on front side of the substrate 12 could be used as connecting junctions such as direct bond interconnects (DBIs) as the two wafers could be bonded through DBIs in the later process. In this embodiment, the ILD layer and the IMD layer 14 could include oxides including but not limited to for example tetraethyl orthosilicate (TEOS) and the contact plugs and the metal interconnections 16 could include Al, Cr, Cu, Ta, Mo, W, or combination thereof.

Next, a dielectric layer 18 is formed on the IMD layer 14. In this embodiment, the dielectric layer 18 is preferably a dual-layer structure having a dielectric layer 20 and another dielectric layer 22, in which the lower level dielectric layer 20 includes silicon nitride (SiN) while the upper level dielectric layer 22 includes silicon oxide, but not limited thereto.

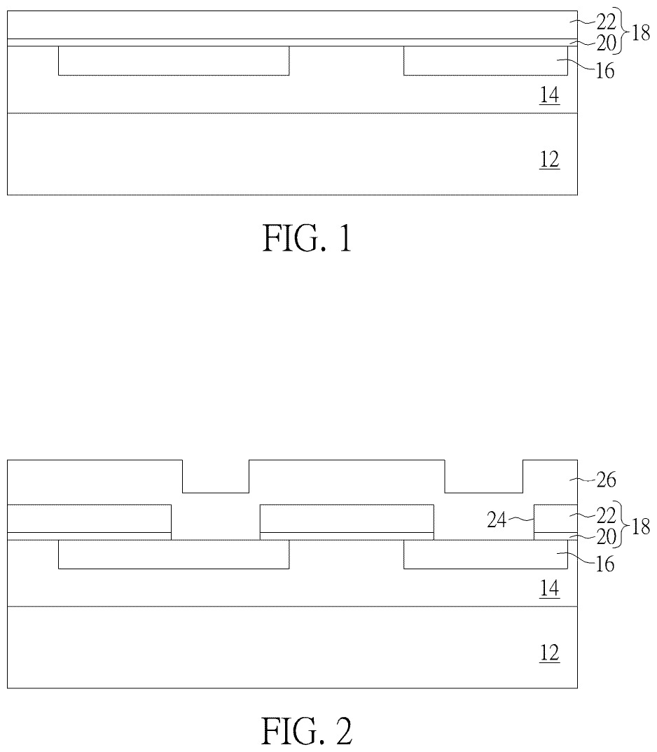

Next, as shown in FIG. 2, the dielectric layer 18 is patterned to form one or a plurality of openings 24. For instance, a photo-etching process could be conducted by using a patterned mask (not shown) such as patterned resist as mask to remove part of the dielectric layer 18 through etching for forming openings 24 exposing the metal interconnections 16 underneath. After striping the patterned mask, a pad layer 26 is formed on the dielectric layer 18 and into the openings 24 completely. In this embodiment, the pad layer 26 preferably includes metal such as aluminum (Al), but not limited thereto. According to other embodiment of the present invention, the pad layer 26 could also include copper (Cu), silver (Ag), gold (Au), nickel (Ni), tungsten (W), or combination thereof.

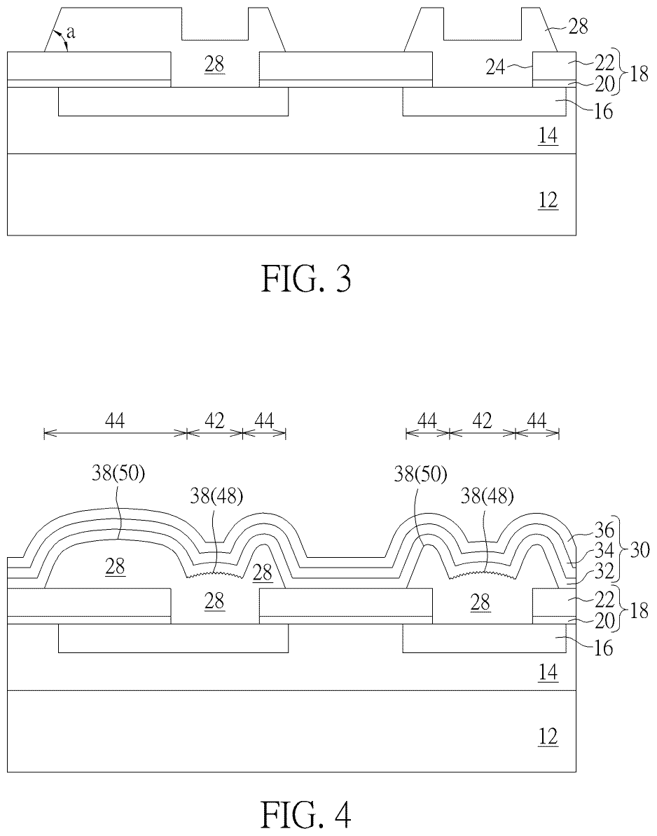

Next, as shown in FIG. 3, another photo-etching process could be conducted by using another patterned mask (not shown) such as patterned resist as mask to remove part of the pad layer 26 through etching such that the pad layer 26 is patterned to form bonding pads 28. It should be noted that the etching process conducted at this stage is carried out at a tilt angle to remove part of the pad layer 26. In particular, sidewalls of the pad layer 26 on top of the dielectric layer 18 are trimmed to form inclined sidewalls such that the remaining pad layer 26 having inclined sidewalls now become the bonding pads 28. According to an embodiment of the present invention, an angle a included between a bottom surface of the bonding pad 28 or top surface of the dielectric layer 18 and the sidewall of the bonding pad 28 is between 60-80 degrees or most preferably 70 degrees.

Next, as shown in FIG. 4, a passivation layer 30 is formed on the bonding pads 28 and the dielectric layer 18, in which the passivation layer 30 further includes a first passivation layer 32, a second passivation layer 34 on the first passivation layer 32, and a third passivation layer 36 on the second passivation layer 34. In this embodiment, the first passivation layer 32 preferably includes silicon oxide while the second passivation layer 34 and third passivation layer 36 include silicon nitride (SiN), in which the stress of the second passivation layer 34 is less than the stress of the third passivation layer 36. For instance, the silicon concentration of the second passivation layer 34 is less than the silicon concentration of the third passivation layer 36. According to a preferred embodiment of the present invention, the lower level second passivation layer 34 having lower stress could be serving as a buffer layer for protecting lower level chips while the upper level third passivation layer 36 having higher stress could be used for adjusting warpage of the entire wafer.

Specifically, after the first passivation layer 32 is formed, it would be desirable to adjust the flow volume of silane and ammonia (NH₃) injected for further adjusting the stress and silicon concentration of the second passivation layer 34 and third passivation layer 36. Preferably, the flow rate of silane injected during formation of the second passivation layer 34 is between 850-1050 sccm or most preferably 950 sccm, the flow rate of ammonia injected during formation of the second passivation layer 34 is between 7000-8000 sccm or most preferably 7500 sccm, the flow rate of silane injected during formation of the third passivation layer 36 is between 300-370 sccm or most preferably 330 sccm, and the flow rate of ammonia injected during formation of the third passivation layer 36 is between 630-770 sccm or most preferably 700 sccm.

Since the ratio of silane to ammonia used during formation of the third passivation layer 36 is significantly greater than the ratio of silane to ammonia used during formation of the second passivation layer 34, the silicon concentration of the third passivation layer 36 formed would therefore be substantially greater than the silicon concentration of the second passivation layer 34. If viewed from another perspective, the third passivation layer 36 now becomes a silicon rich SiN layer compared to the second passivation layer 34. Moreover, the thickness of the first passivation layer 32 is between 2000-6000 Angstroms or most preferably 4000 Angstroms, the thickness of the second passivation layer 34 is between 1400-4500 Angstroms or most preferably 3000 Angstroms, and the thickness of the third passivation layer 36 is between 2500-7500 Angstroms or most preferably 5000 Angstroms.

It should also be noted that after the passivation layer 30 is formed on the bonding pads 28, an optional thermal treatment process could be conducted by using a temperature greater than 450° C. or most preferably between 450° C. to 500° C. to transform the planar top surface and planar sidewalls of the bonding pads 28 into curves or curved surfaces 38. Specifically, the thermal treatment process is conducted when the passivation layer 30 is disposed on top of the bonding pads 28 to alter the profile of the top surface and sidewalls of the bonding pads 28. By doing so, the bonding pads 28 could be divided into portions in regions 42 between the patterned dielectric layer 18 and directly on top of the metal interconnection 16 and portions in regions 44 directly above the dielectric layer 18, in which the top surface of the bonding pads 28 on the regions 42 and the top surface of the bonding pads 28 on the regions 44 preferably have different curve profile due to different temperature of the elements underneath.

According to an embodiment of the present invention, since the metal interconnection 16 includes higher residual temperature while the dielectric layer 18 includes lower residual temperature after the aforementioned thermal treatment process is conducted, the top surface of the bonding pad 28 directly on top of the metal interconnection 16 in the regions 42 would not only demonstrate a curved surface 38 overall but also include a rough surface 48 at the same time. The top surface of the bonding pad 28 directly above the dielectric layer 18 in the regions 44 on the other hand would not only exhibit a curved surface 38 overall but also include a planar surface 50. Preferably, the definition of a rough surface 48 could be interpreted as top surface of the bonding pads 28 having wave like surface or irregular ups and downs such as plurality of protrusions, indentations, or combination thereof.

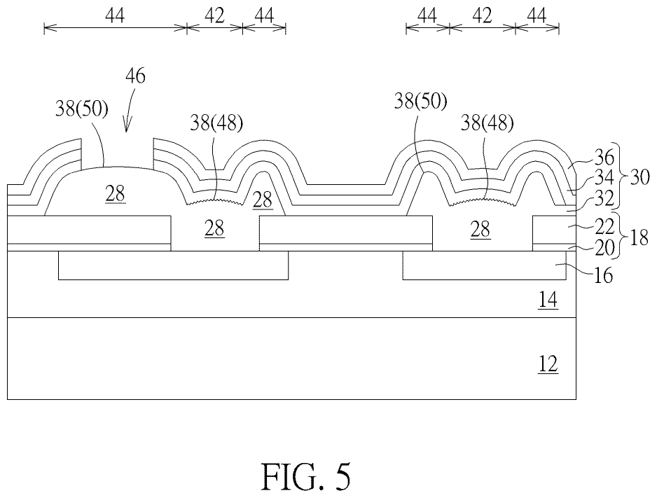

Next, as shown in FIG. 5, a photo-etching process could be conducted by using a patterned mask such as patterned resist as mask to remove part of the passivation layer 30 through etching to form at least an opening 46 exposing part of the bonding pad 28. Next, packaging process such as wire bonding could be carried out for connecting other chips or dies depending on the demand of the product. This completes the fabrication of a semiconductor device according to an embodiment of the present invention.

Overall, the present invention first forms a metal interconnection 16 in the IMD layer 14, forms a dielectric layer 18 on the IMD layer, patterns the dielectric layer to form an opening 24, forms a bonding pad 28 in the opening, forms multiple passivation layers including a first passivation layer 32, a second passivation layer 34, and a third passivation layer 36 on the bonding pad, and then conducts a thermal treatment process to transform the top surface and sidewalls of the bonding pad into curved surface. According to a preferred embodiment of the present invention, the second passivation layer 34 and third passivation layer 36 from the passivation layer stack preferably have different stress, in which the lower level second passivation layer 34 having lower stress could be serving as a buffer layer for protecting lower level chips while the upper level third passivation layer 36 having higher stress alone with the curved surface of the bonding pads could be used for adjusting warpage of the entire wafer and increasing overall strength of the chip.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming an inter-metal dielectric ((IMD) layer on a substrate and a metal interconnection in the IMD layer;
forming a dielectric layer on the IMD layer;
patterning the dielectric layer to form an opening;
forming a bonding pad in the opening; and
forming a passivation layer on the bonding pad, wherein a top surface of the bonding pad comprises a first curve.

2. The method of claim 1, further comprising:
forming a pad layer on the dielectric layer and into the opening;
patterning the pad layer to form the bonding pad; and
forming the passivation layer on the bonding pad while transforming the top surface of the bonding pad into the first curve.

3. The method of claim 2, further comprising forming the passivation layer on the bonding pad while transforming a sidewall of the bonding pad to form a second curve.

4. The method of claim 1, wherein the passivation layer comprises:
a first passivation layer;
a second passivation layer on the first layer; and
a third passivation layer on the second passivation layer.

5. The method of claim 4, wherein the first passivation layer comprises silicon oxide.

6. The method of claim 4, wherein the second passivation layer and the third passivation layer comprise silicon nitride.

7. The method of claim 4, wherein a stress of the second passivation layer is less than a stress of the third passivation layer.

8. The method of claim 4, wherein a silicon concentration of the second passivation layer is less than a silicon concentration of the third passivation layer.

9. A semiconductor device, comprising:
an inter-metal dielectric ((IMD) layer on a substrate and a metal interconnection in the IMD layer;
a dielectric layer on the IMD layer; and
a bonding pad on the dielectric layer, wherein a top surface of the bonding pad comprises a first curve.

10. The semiconductor device of claim 9, wherein a sidewall of the bonding pad comprises a second curve.

11. The semiconductor device of claim 9, further comprising a passivation layer on part of the bonding pad.

12. The semiconductor device of claim 11, wherein the passivation layer comprises:
a first passivation layer;
a second passivation layer on the first layer; and
a third passivation layer on the second passivation layer.

13. The semiconductor device of claim 12, wherein the first passivation layer comprises silicon oxide.

14. The semiconductor device of claim 12, wherein the second passivation layer and the third passivation layer comprise silicon nitride.

15. The semiconductor device of claim 12, wherein a stress of the second passivation layer is less than a stress of the third passivation layer.

16. The semiconductor device of claim 12, wherein a silicon concentration of the second passivation layer is less than a silicon concentration of the third passivation layer.
